(19) United States
(12) Patent Application Publication
(10) Pub. No.: US 2026/0107548 A1
(43) Pub. Date: Apr. 16, 2026

(54) SEMICONDUCTOR STRUCTURE WITH REDUCED PARASITIC CAPACITANCE AND METHOD FOR MANUFACTURING THE SAME

(71) Applicant: Taiwan Semiconductor Manufacturing Company, Ltd., Hsinchu (TW)

(72) Inventors: Wan-Ting KUNG, Hsinchu (TW); Hsiang-Pi CHANG, Hsinchu (TW); Hsu-Kai CHANG, Hsinchu (TW); Huang-Lin CHAO, Hsinchu (TW); Pinyen LIN, Hsinchu (TW); Kenichi SANO, Hsinchu (TW)

(73) Assignee: Taiwan Semiconductor Manufacturing Company, Ltd., Hsinchu (TW)

(21) Appl. No.: 18/916,128

(22) Filed: Oct. 15, 2024

(51) Int. Cl. H01L 29/423; H01L 21/28; H01L 29/06; H01L 29/417; H01L 29/66; H01L 29/775; H01L 29/786

(52) U.S. Cl. CPC H10D 64/514; H10D 30/014; H10D 62/116; H10D 64/013; H10D 64/021; H10D 64/258; H10D 30/43; H10D 30/6735; H10D 30/6757; H10D 62/121

(57) ABSTRACT

A method for manufacturing a semiconductor structure includes: forming a gate dielectric layer on a patterned structure, the gate dielectric layer having a first dielectric region and a second dielectric region displaced from each other; forming a cladding layer on the gate dielectric layer, a material of the cladding layer being different from that of the gate dielectric layer; introducing ions into the first dielectric region through the cladding layer while the second dielectric region is shielded from the ions, such that a concentration of the ions in the first dielectric region is greater than a concentration of the ions in the second dielectric region; and removing the cladding layer to expose the gate dielectric layer; and after removing the cladding layer, removing the first dielectric region to expose a first surface of the patterned structure while the second dielectric region remains on a second surface of the patterned structure.

### BACKGROUND

With rapid development of semiconductor technology, critical dimension (CD) of transistors keeps shrinking and a distance between two conductive elements is continuously reduced, resulting in an increased parasitic capacitance between the two conductive elements. Therefore, reduction in the parasitic capacitance generated in an integrated circuit is required in order to alleviate resistance-capacitance (RC) time delay.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a method for manufacturing a semiconductor structure in accordance with some embodiments.

FIGS. 2 to 16 illustrate schematic views of intermediate stages of the method depicted in FIG. 1 in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “top,” “bottom,” “upper,” “lower,” “over,” “beneath,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, or other numerical values used in the specification and claims, are to be understood as being modified in all instances by the terms “about” and “substantially” even if the terms “about” and “substantially” are not explicitly recited with the values, amounts or ranges. Accordingly, unless indicated to the contrary, the numerical parameters set forth in the following specification and appended claims are not and need not be exact, but may be approximations and/or larger or smaller than specified as desired, may encompass tolerances, conversion factors, rounding off, measurement error, and other factors known to those of skill in the art depending on the desired properties sought to be obtained by the presently disclosed subject matter. For example, the terms “about” and “substantially,” when used with a value, can capture variations of, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

The term “source/drain feature(s)” may refer to a source or a drain, individually or collectively dependent upon the context.

During formation of a gate dielectric layer on a channel layer of a transistor, the material of the gate dielectric layer may also be deposited on gate spacers of the transistor. In such case, a parasitic capacitance formed between a gate electrode and a source/drain contact of the transistor may be relatively high due to the presence of the material of the gate dielectric layer (which may be made of a high dielectric constant (high-k) material) between the gate electrode and the source/drain contact. Therefore, the present disclosure is directed to a method for removing the material of the gate dielectric layer which is deposited on the gate spacers, and a semiconductor structure manufactured thereby. In the following, manufacturing of the semiconductor structure that is configured as a gate-all-around (GAA) structure is exemplarily described for the purpose of illustrating the method of the present disclosure.

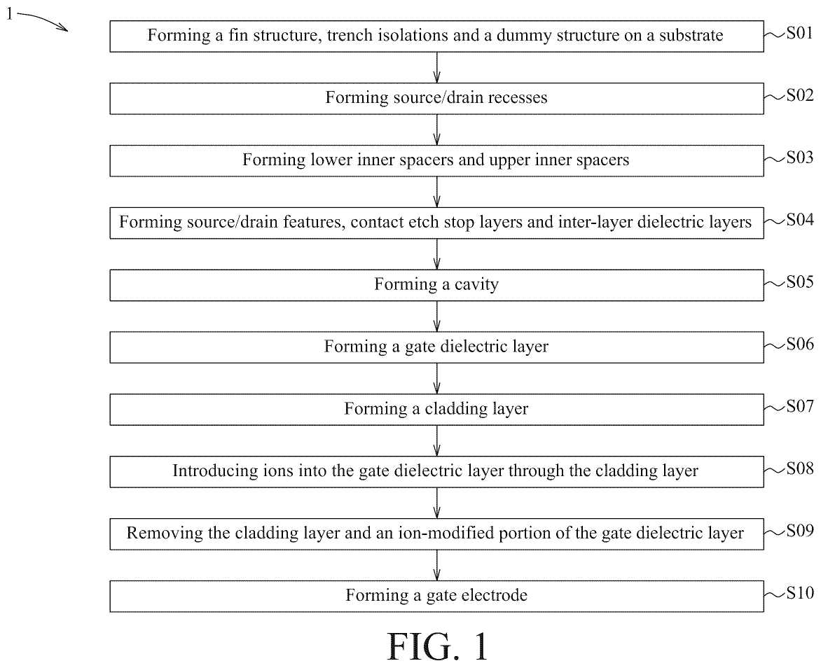

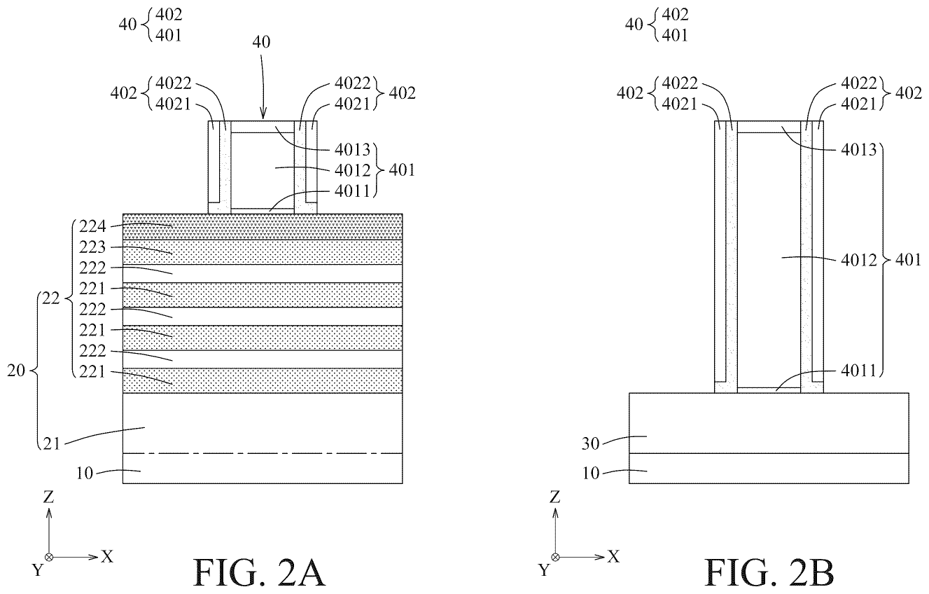

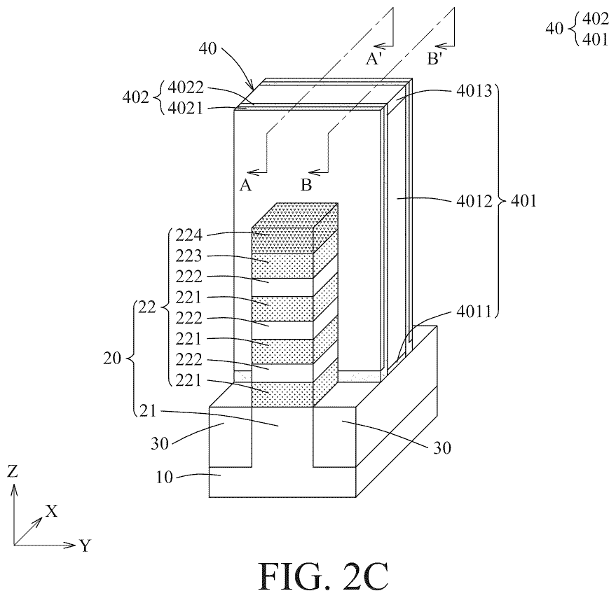

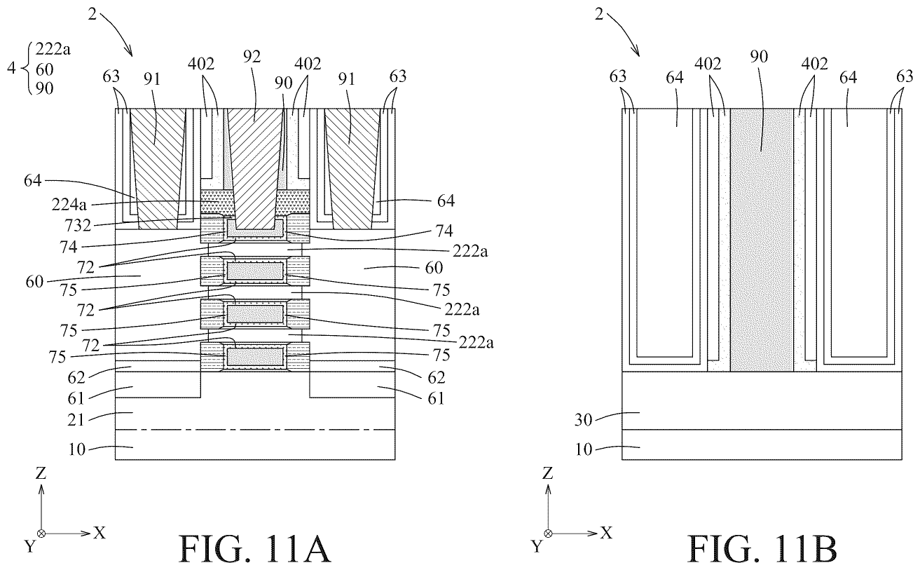

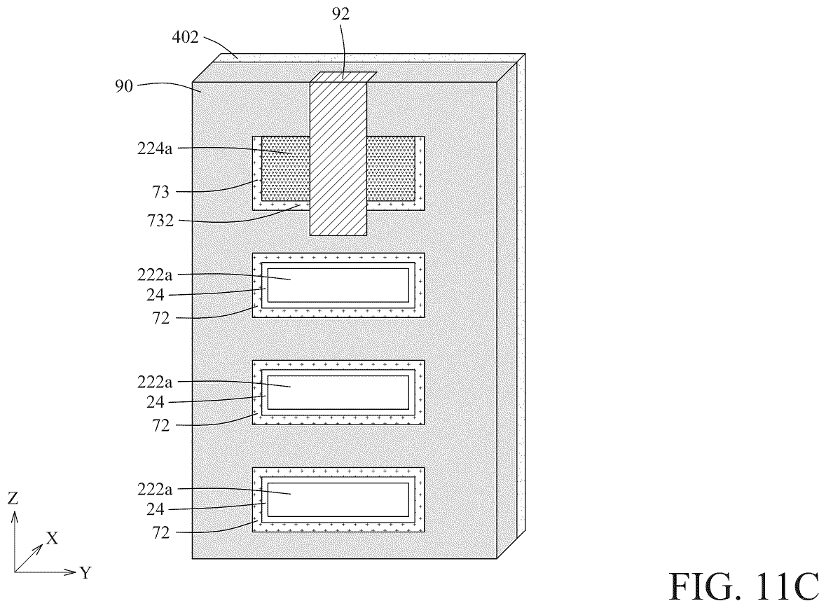

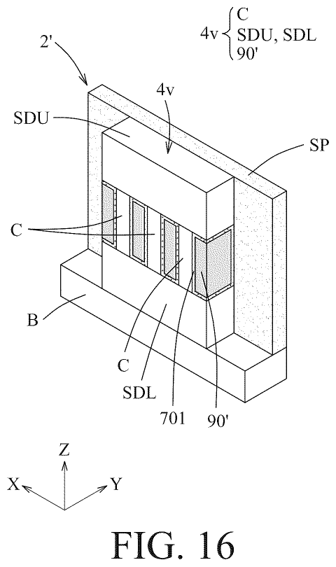

FIG. 1 is a flow diagram illustrating a method 1 for manufacturing a semiconductor structure (for example, but not limited to, a semiconductor structure 2 shown in FIGS. 11A and 11B or a semiconductor structure 2′ shown in FIG. 16) in accordance with some embodiments. FIGS. 2 to 16 illustrate schematic views of intermediate stages of the method 1 in accordance with some embodiments.

Referring to FIG. 1 and the examples illustrated in FIGS. 2A to 2C, the method 1 begins at step S01, where a fin structure 20, two trench isolations 30 and a dummy structure 40 are formed on a substrate 10. FIGS. 2A and 2B are schematic sectional views respectively taken along line A-A′ and line B-B′ of FIG. 2C in accordance with some embodiments.

In some embodiments, the substrate 10 may include elemental semiconductor materials (such as crystalline silicon, diamond, or germanium), compound semiconductor materials (such as silicon carbide, gallium arsenide, indium arsenide, or indium phosphide), alloy semiconductor materials (such as silicon germanium, silicon germanium carbide, gallium arsenide phosphide, or gallium indium phosphide), or combinations thereof. In some embodiments, the substrate 10 may be a bulk semiconductor substrate, for example, but not limited to, a bulk substrate of silicon, germanium, silicon germanium, or other suitable semiconductor materials (such as the examples described earlier in the same paragraph). In some embodiments, the substrate 10 may be formed with an n-type well having an n-type conductivity or a p-type well having a p-type conductivity. Each of the n-type well and the p-type well may be formed by introducing an n-type impurity or a p-type impurity into the substrate 10 by an implantation processes. In some embodiments, the n-type impurity may include phosphorous (P, ³¹P), arsenic (As), antimony (Sb), or combinations thereof. In some embodiments, the p-type impurities may include boron or boron compound (for example, B, ¹¹B, BF₂), aluminum (Al), indium (In), gallium (Ga), or combinations thereof. In some other embodiments not shown herein, the substrate 10 may be configured as a semiconductor-on-insulator substrate. Other suitable materials and configurations for the substrate 10 are within the contemplated scope of the present disclosure.

The fin structure 20 is formed on the substrate 10 and is elongated in an X direction. The fin structure 20 includes a fin 21 and a stack 22 which is disposed on the fin 21. In some embodiments, the fin 21 may be implanted with a p-type impurity to serve as a p-type well, or may be implanted with an n-type impurity to serve as an n-type well. The examples of the p-type impurity and the n-type impurity are similar to those as described in the previous paragraph.

The stack 22 includes first sacrificial layers 221, channel layers 222 disposed to alternate with the first sacrificial layers 221 in a Z direction transverse the X direction, a second sacrificial layer 223 disposed on an uppermost one of the channel layers 222 opposite to an uppermost one of the first sacrificial layers 221, and a shielding layer 234 disposed on the second sacrificial layer 223 opposite to the uppermost one of the channel layers 222. A lowermost one of the channel layers 222 is spaced apart from the fin 21 by a lowermost one of the first sacrificial layers 221.

Each of the sacrificial layers 221, 223 is made of a first semiconductor material, and each of the channel layers 222 is made of a second semiconductor material that is different from the first semiconductor material, so that the sacrificial layers 221, 223 are able to be selectively removed while the channel layers 222 are substantially intact due to different etching selectivity ratios. Possible semiconductor materials suitable for forming the sacrificial layers 221, 223 and the channel layers 222 are similar to those for forming the substrate 10, and thus the details thereof are omitted for the sake of brevity. In some embodiments, each of the sacrificial layers 221, 223 is made of silicon germanium, and each of the channel layers 222 is made of silicon. Other materials suitable for the sacrificial layers 221, 223 and the channel layers 222 are within the contemplated scope of the present disclosure.

The shielding layer 224 is made of a dielectric material. In some embodiments, the shielding layer 224 is made of a nitride-based material which includes silicon nitride, silicon oxynitride, silicon carbon nitride, silicon oxycarbon nitride, other suitable nitride-based materials with low dielectric constant (k), or combinations thereof.

In some embodiments, each of the sacrificial layers 221, 223 has a thickness ranging from about 4 nm to about 14 nm. In some embodiments, each of the channel layers 222 has a thickness ranging from about 3 nm to about 9 nm, or ranging from about 5 nm to about 8 nm. In some embodiments, the shielding layer 224 has a thickness ranging from about 3 nm to about 9 nm, or ranging from about 5 nm to about 8 nm. In some embodiments, each of the channel layers 222 and the shielding layer 224 has a width in a Y direction ranging from about 15 nm to about 50 nm. The Y direction is transverse to the X and Z directions. In some embodiments, the X, Y and Z directions are perpendicular to each other.

In some embodiments, formation of the fin structure 20 may include (i) forming a lamination structure (not shown) on a starting substrate (not shown) by CVD, ALD, an epitaxial growth process (such as molecular-beam epitaxy (MBE), selective area epitaxy (SAE), etc.), or other suitable deposition techniques, and (ii) patterning the lamination structure and the starting substrate using a photolithography process followed by an etching process. As a result, the lamination structure is patterned into the stack 22 of the fin structure 20 each having a predetermined dimension in the Y direction, and the starting substrate is patterned into the substrate 10 and the fin 21 of the fin structure 20.

The two trench isolations 30 are respectively located at two opposite sides of the fin structure 20 in the Y direction. In some embodiments, the trench isolations 30 may each be a shallow trench isolation (STI), a deep trench isolation (DTI), or other suitable structures. In some embodiments, the trench isolations 30 may include silicon oxide, silicon nitride, silicon oxynitride, other low-k dielectric materials, or combinations thereof. Other insulating materials suitable for the trench isolations 30 are within the contemplated scope of the present disclosure.

In some embodiments, formation of the trench isolations 30 may include (i) forming an isolation layer over the substrate 10 and the fin structure 20 followed by a planarization process (for example, but not limited to, chemical mechanism polishing (CMP)) to form two isolation regions (not shown) respectively located at the two opposite sides of the fin structure 20 in the Y direction, and (ii) recessing the two isolation regions until the lowermost one of the first sacrificial layers 221 is exposed, such that the two isolation regions are respectively formed into the two trench isolations 30.

In some embodiments, the substrate 10, the fin 21 and the trench isolations 30 may together referred to as a base structure.

The dummy structure 40 is elongated in the Y direction and is formed over the fin structure 20 and the trench isolations 30, so that the fin structure 20 has two exposed portions which are exposed from the dummy structure 40 and which are respectively disposed at two opposite sides of the dummy structure 40 in the X direction.

The dummy structure 40 includes a main portion 401, and two gate spacers 402 respectively disposed at two opposite sides of the main portion 401 in the X direction.

The main portion 401 includes a dummy dielectric 4011, a dummy gate 4012, and a hard mask 4013. The dummy dielectric 4011 is disposed on the base structure and across over the fin structure 20. The dummy gate 4012 and the hard mask 4013 are sequentially formed on the dummy dielectric 4011 opposite to the base structure. In some embodiments, the dummy dielectric 4011 may include silicon oxide, silicon nitride, silicon oxynitride, high dielectric constant (k) materials, other suitable dielectric materials, or combinations thereof. In some embodiments, the dummy gate 4012 may include polycrystalline silicon, single crystalline silicon, amorphous silicon, or combinations thereof. In some embodiments, the hard mask 4013 may include silicon nitride, silicon oxide, silicon oxynitride, or combinations thereof. Other materials suitable for the main portion 401 are within the contemplated scope of the present disclosure. In some embodiments, formation of the main portion 401 may include (i) sequentially forming a first dummy layer (not shown) for forming the dummy dielectric 4011 and a second dummy layer (not shown) for forming the dummy gate 4012 on the base structure and across over the fin structure 20 by CVD, ALD, physical vapor deposition (PVD), or other suitable deposition techniques, (ii) performing a planarization process (e.g., chemical mechanical polishing) to obtain a planar upper surface of the second dummy layer, (iii) forming a third dummy layer (not shown) for forming the hard mask 4013 on the planarized second dummy layer, and (iv) patterning the first dummy layer, the planarized second dummy layer and the third dummy layer to partially expose the fin structure 20 and the trench isolations 30 using a photolithography process followed by an etching process, thereby obtaining the main portion 401.

In some embodiments, each of the gate spacers 402 may be configured as a single layer structure or a multi-layered structure. In some embodiments, as shown in FIGS. 2A to 2C, each of the spacers 402 is formed as a bi-layer structure, and includes an outer sub-layer 4021 and an inner sub-layer 4022 which is disposed between the outer sub-layer 4021 and the main portion 401. The outer and inner sub-layers 4021, 4022 are made of different materials. In some embodiments, possible materials suitable for the gate spacers 306 may include, for example, but not limited to, a silicon oxide (e.g., SiO₂) based dielectric material, a silicon nitride (e.g., Si₃N₄) based dielectric material, a carbon-doped silicon oxide material, a nitride-doped silicon oxide material, a porous oxide material, other suitable low-k dielectric materials, or combinations thereof. In some embodiments, formation of the gate spacers 402 includes (i) conformally depositing material(s) of the gate spacers 402 to cover the main portion 401, the fin structure 20 and the trench isolations 30 by CVD, ALD, PVD, or other suitable deposition techniques, and (ii) performing an anisotropic etching process on the material(s) of the gate spacers 402 to remove horizontal portions of the material(s) of the gate spacers 402, while vertical portions of the material(s) of the gate spacers 402 respectively remain at two side surfaces of the main portion 401, and respectively serve as the gate spacers 402. In some embodiments, during formation of the gate spacers 402, the material(s) of the gate spacers 402 is also formed into two pairs of fin sidewalls (not shown). Each pair of the fin sidewalls are respectively formed at two opposite sides of a respective one of the exposed portions of the fin structure 20 in the Y direction.

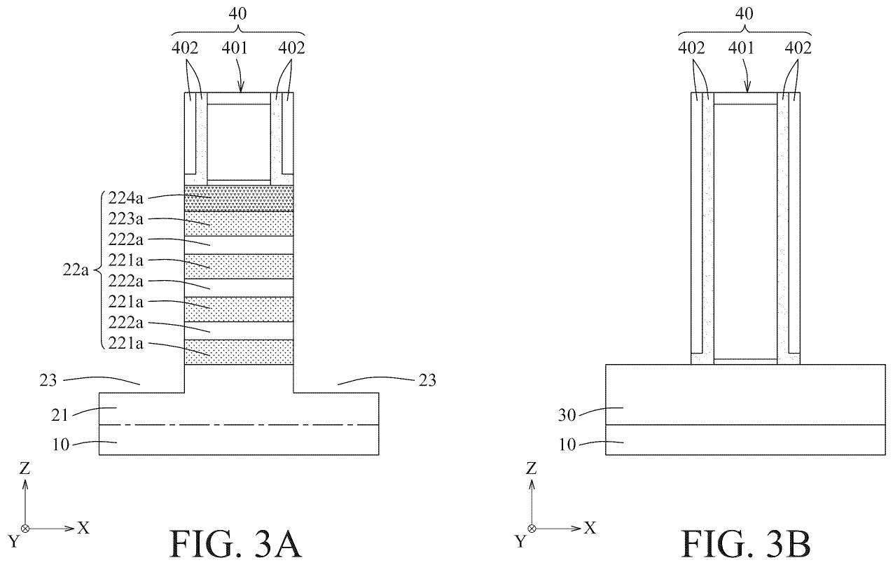

Referring to FIG. 1 and the examples illustrated in FIGS. 3A and 3B, the method 1 proceeds to step S02, where the exposed portions of the fin structure 20 (see FIG. 2A) are patterned to form source/drain recesses 23, respectively, by an etching technique (for example, but not limited to, dry etching, wet etching, or a combination thereof). FIGS. 3A and 3B are schematic sectional views respectively similar to those of FIGS. 2A and 2B, but illustrating the structure after step S02.

In step S02, the stack 22 (see FIG. 2A) is patterned into a stacking portion 22a which is located beneath the dummy structure 40, and two portions of the fin 21 are respectively exposed from the source/drain recesses 23. In some embodiments, the exposed portions of the fin 21 are further etched to deepen the source/drain recesses 23. The stacking portions 22a are disposed between the source/drain recesses 23. Each of the stacking portions 22a includes first sacrificial films 221a which are respectively formed from the first sacrificial layers 221, channel films 222a which are respectively formed from the channel layers 222, a second sacrificial film 223a which is formed from the second sacrificial layer 223, and a shielding film 224a which is formed from the shielding layer 224. The gate spacers 402 respectively extend across over two end regions E4 of the shielding film 224a. The two end regions E4 are spaced apart and opposite to each other in the X direction.

The channel films 222a may be also referred to as channel features, and the shielding film 224a may be also referred to as a shielding feature.

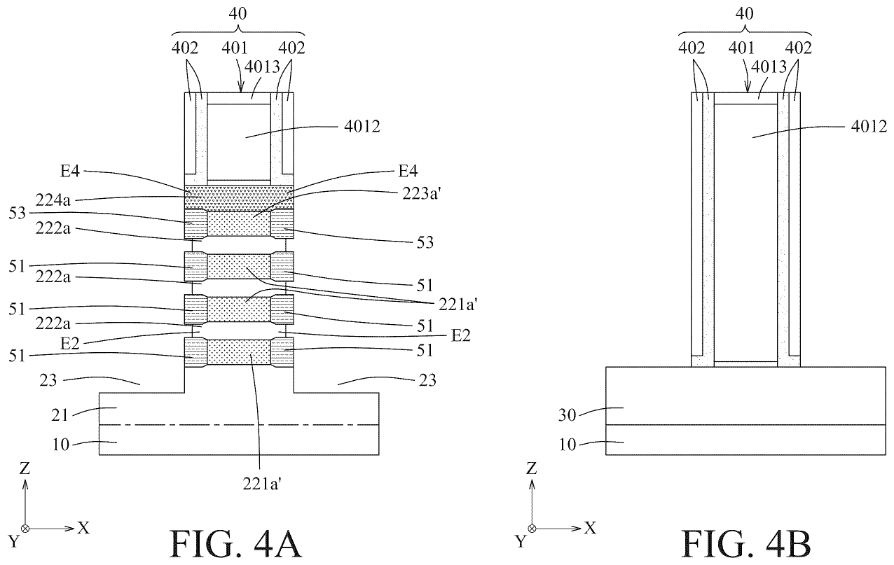

Referring to FIG. 1 and the examples illustrated in FIGS. 4A and 4B, the method 1 proceeds to step S03, where multiple pairs of lower inner spacers 51 and two upper inner spacers 53 are formed. FIGS. 4A and 4B are schematic sectional views respectively similar to those of FIGS. 3A and 3B, but illustrating the structure after step S03.

In some embodiments, formation of the inner spacers 51, 53 may include (i) recessing two end regions of each of the sacrificial films 221a, 223a opposite to each other in the X direction (see FIG. 3A) to form lateral recesses (not shown) by an etching process while keeping the channel films 222a and the shielding film 224a substantially intact, (ii) depositing a low-k dielectric material for forming the inner spacers 51, 53 to cover each of the recessed sacrificial films 221a′, 223a′ and fill the lateral recesses by CVD, ALD, PVD, or other suitable deposition techniques, and (iii) remove excess portions of the low-k dielectric material for forming the inner spacers 51, 53 by an anisotropic etching process to expose the channel films 222a, the shielding film 224a and the fin 21.

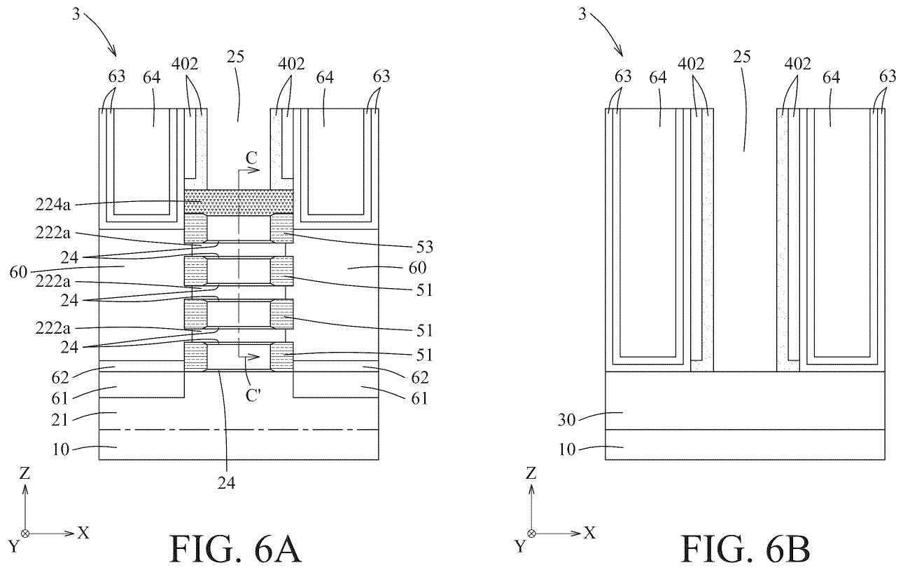

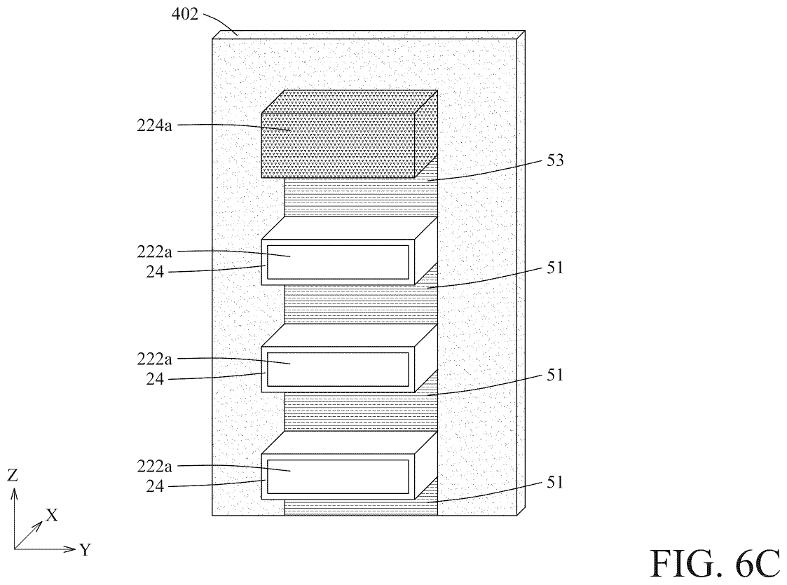

Accordingly, each pair of the lower inner spacers 51 are respectively formed at two opposite sides of a respective one of the recessed sacrificial films 221a', and are respectively located beneath two end regions E2 of a respective one of the channel films 222a. The two end regions E2 are spaced apart and opposite to each other in the X direction. In each pair of the lower inner spacers 51, each of the lower inner spacers 51 (one of which is shown in FIG. 6C) is connected to a respective one of the two gate spacers 402.

The two upper inner spacers 53 are respectively formed at two opposite sides of the recessed sacrificial films 223a′, and are respectively located beneath the two end regions E4 of the shielding film 224a. Each of the two upper inner spacers 53 (one of which is shown in FIG. 6C) is connected to a respective one of the two gate spacers 402.

In some embodiments, the low-k dielectric material for forming the inner spacers 51, 53 may include silicon oxide, silicon nitride, silicon oxynitride, silicon carbonitride, silicon oxycarbide, silicon oxycarbonitride, silicon carbide, other suitable low-k dielectric materials, or combinations thereof. Other low-k dielectric materials suitable for the inner spacers 51, 53 are within the contemplated scope of the present disclosure.

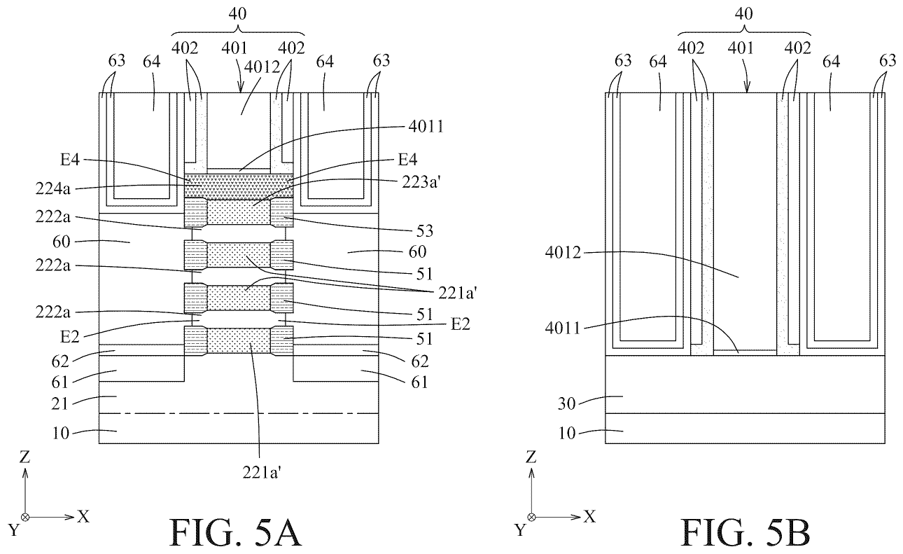

Referring to FIG. 1 and the examples illustrated in FIGS. 5A and 5B, the method 10 proceeds to step S04, where two source/drain features 60 are respectively formed to fill the two source/drain recesses 23 (see FIG. 4A), and then two contact etch stop layers (CESLs) 63 and two inter-layer dielectric (ILD) layers 64 are formed. Each of the CESLs 63 is formed on the trench isolations 30 (one of which is shown in FIG. 5B) and a respective one of the source/drain features 60. The ILD layers 64 are respectively formed on the CESLs 63. FIGS. 5A and 5B are schematic sectional views respectively similar to those of FIGS. 4A and 4B, but illustrating the structure after step S04.

In some embodiments, prior to formation of the source/drain features 60, epitaxial portions 61 and dielectric portions 62 are formed. The epitaxial portions 61 are respectively formed in lower regions of the source/drain recesses 23, and the dielectric portions 62 are respectively formed on the epitaxial portions 61. The dielectric portions 62 are spaced apart from a lowermost one of the channel films 222a.

In some embodiments, each of the epitaxial portions 61 includes a semiconductor material (such as the examples of the semiconductor material for forming the substrate 10). In some embodiments, each of the epitaxial portions 61 is made of silicon. In some embodiments, each of the epitaxial portions 61 is formed by an epitaxial growth process (such as molecular-beam epitaxy (MBE), selective area epitaxy (SAE), etc.), or other suitable deposition techniques. In some embodiments, each of the dielectric portions 62 includes a dielectric material (such as the examples of the dielectric material for forming the inner spacers 51, 53). In some embodiments, the dielectric portions 62 may be formed by a deposition process, followed by an isotropic etching process, and/or other suitable techniques.

In some embodiments, after formation of the epitaxial portions 61 and the dielectric portions 62 and before formation of the source/drain features 60, an etching process may be performed to reduce a dimension of the channel films 222a in the X direction while keeping the shielding film 224a, the dummy structure 40 and the inner spacers 51, 53 intact.

Each of the source/drain features 60 is epitaxial grown from corresponding ones of the end regions E2 of the channel films 222a. Hence, the two source/drain features 60 are respectively connected to the end regions E2 of each of the channel films 222a, and are respectively spaced apart from the end regions E4 of the shielding film 224a.

In some embodiments, each of the source/drain features 60 may include single crystalline silicon, polycrystalline silicon or other suitable materials. In some embodiments, the source/drain features 60 may be doped with n-type impurities so as to function as source/drain regions of an n-FET. The n-type impurities may be, for example, but not limited to, nitrogen (N), phosphorous (P), arsenic (As), antimony (Sb), other suitable materials, or combinations thereof. In some other embodiments, the source/drain features 60 may be doped with p-type impurities so as to function as source/drain regions of a p-FET. The p-type impurities may be, for example, but not limited to, boron (B), aluminum (Al), gallium (Ga), indium (In), other suitable materials, or combinations thereof. In some embodiments, each of the source/drain features 60 may be formed as a multi-layered structure having several sub-layers (not shown) with different doping concentration and/or different dopants. In some embodiments, each of the source/drain features 60 may be formed as a single layer structure. In some embodiment, the two source/drain features 60 may be formed by an epitaxial growth process including molecular-beam epitaxy (MBE), an epitaxial deposition/partial etch process, such as a cyclic deposition-etch (CDE) process and/or a selective epitaxial growth (SEG) process, but the disclosure is not limited to such.

In some embodiments, the ILD layers 64 may include a low-k dielectric material, such as silicon oxynitride, phosphosilicate glass (PSG), borosilicate glass (BSG), borophosphosilicate glass (BPSG), undoped silicate glass (USG), fluorinated silicate glass (FSG), silicon oxycarbide (SiOC), spin-on-glass (SOG), or combinations thereof. Other dielectric materials suitable for the ILD layers 64 are within the contemplated scope of the present disclosure. The CESLs 63 include a material different from the dielectric material of the ILD layers 64. In some embodiments, the CESLs 63 include silicon nitride, carbon-doped silicon nitride, and a combination thereof. Other dielectric materials suitable for the CESLs 63 and the ILD layers 64 are within the contemplated scope of the present disclosure. In some embodiments, each of the CESLs 63 is formed as bi-layer structure.

In some embodiments, formation of the CESLs 63 and the ILD layers 64 may include (i) forming a first material layer (not shown) for forming the two CESLs 63 to cover the two source/drain features 60 and the dummy structure 40 (see FIG. 4A) by a suitable deposition process, (ii) forming a second material layer (not shown) for forming the two ILD layers 64 on the first material layer by a suitable deposition process, and (iii) performing a planarization process until the dummy gate 4012 of the dummy structure 40 (see FIGS. 4A and 4B) is exposed such that the first material layer is formed into the CESLs 63, and such that the second material layer is formed into the ILD layers 64.

Referring to FIG. 1 and the examples illustrated in FIGS. 6A, 6B and 6C, the method 1 proceeds to step S05, where the dummy gate 4012, the dummy dielectric 4011 (see FIGS. 5A and 5B) and the recessed sacrificial films 221a′, 223a′ (see FIG. 5A) are removed to form a cavity 25, and then interfacial layers 24 are formed, thereby obtaining a patterned structure 3. FIGS. 6A and 6B are schematic sectional views respectively similar to those of FIGS. 5A and 5B, but illustrating the structure after step S05. FIG. 6C is an enlarged fragmentary perspective view of a portion of the pattern structure 3 taken from a sectional plane along line C-C′ of FIG. 6A in accordance with some embodiments.

In some embodiments, the dummy gate 4012, the dummy dielectric 4011 and the recessed sacrificial films 221a′, 223a′ may be removed by one or more suitable etching processes (for example but not limited to, a wet etching process, a dry etching process, or a combination thereof).

In some embodiments, as shown in FIGS. 6A and 6C, the interfacial layers 24 are respectively formed around the channel films 222a. In some embodiments, the interfacial layers 24 include a nitrogen-free dielectric material (i.e., a dielectric material free of nitrogen), for example, but not limited to, silicon oxide. In some embodiments, the interfacial layers 24 may be formed by a thermal oxidation, a wet chemical oxidation, ALD, or other suitable deposition processes. In some embodiments, as shown in FIG. 6A, when the interfacial layers 24 are formed by the wet chemical oxidation or the thermal oxidation as abovementioned, surface portions of the channel films 222a which are exposed to an oxidizing agent (e.g., oxygen gas, ozonated aqueous solutions, or a mixture of ammonium hydroxide, hydrogen peroxide and water) used in the thermal oxidation or the wet chemical oxidation, may be oxidized to form the interfacial layers 24. Since the fin 21 is also exposed the oxidizing agent, a surface portion of the fin is oxidized to form an interfacial layer which is also denoted by the numeral 24.

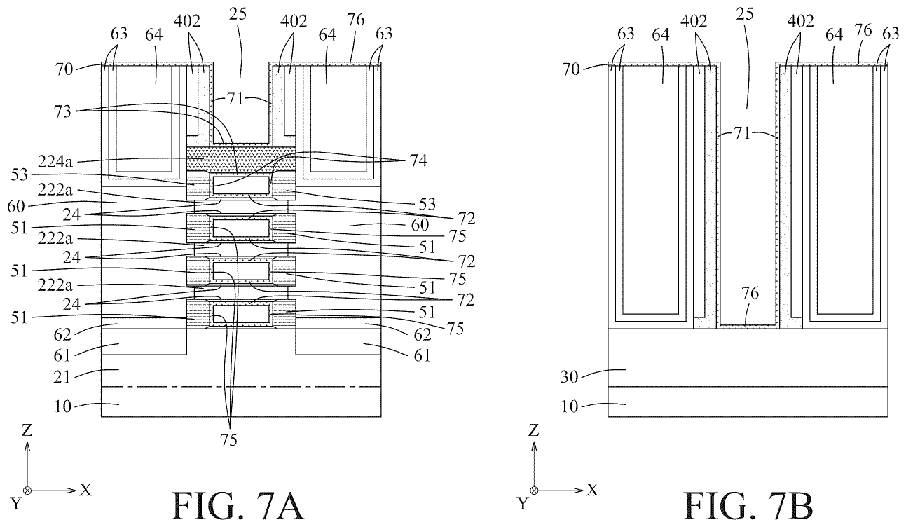

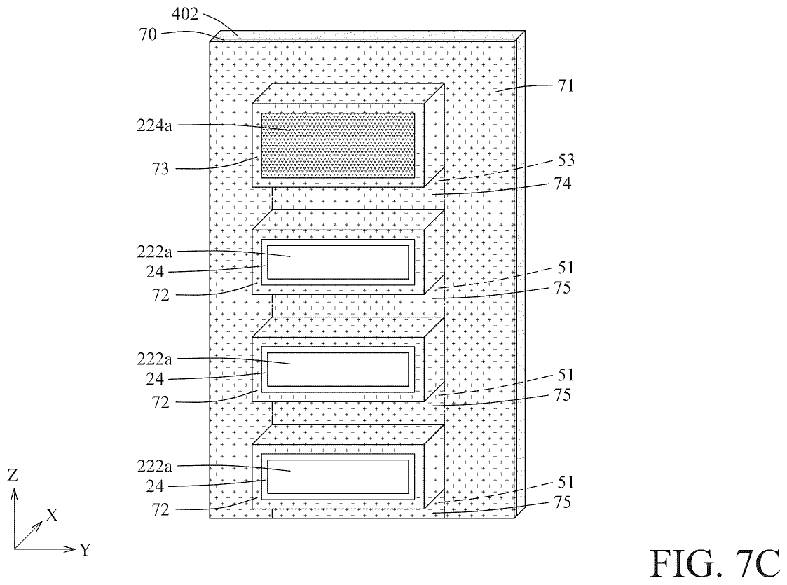

Referring to FIG. 1 and the examples illustrated in FIGS. 7A, 7B and 7C, the method 1 proceeds to step S06, where a gate dielectric layer 70 is formed on the patterned structure 3. FIGS. 7A, 7B and 7C are views respectively similar to those of FIGS. 6A, 6B and 6C, but illustrating the structure after step S06.

In some embodiments, the gate dielectric layer 70 includes silicon oxide, silicon nitride, silicon oxynitride, a suitable high-k material (such as hafnium oxide, zirconium oxide, zirconium aluminum oxide, hafnium aluminum oxide, hafnium silicon oxide, aluminum oxide, etc.), other suitable materials, or combinations thereof. Other dielectric materials suitable for the gate dielectric layer 70 are within the contemplated scope of the present disclosure. In some embodiments, the gate dielectric layer 70 may be formed by CVD, ALD, PVD, or other suitable deposition techniques.

The gate dielectric layer 70 has two first regions 71 respectively formed on the two gate spacers 402, second regions 72 respectively formed on the channel films 222a, a third region 73 formed on the shielding film 224a, two fourth regions 74 respectively formed on the upper inner spacers 53, fifth regions 75 respectively formed on the lower inner spacers 51, and a sixth region 76 formed on the CESLs 63, the ILD layers 64 and the trench isolations 30.

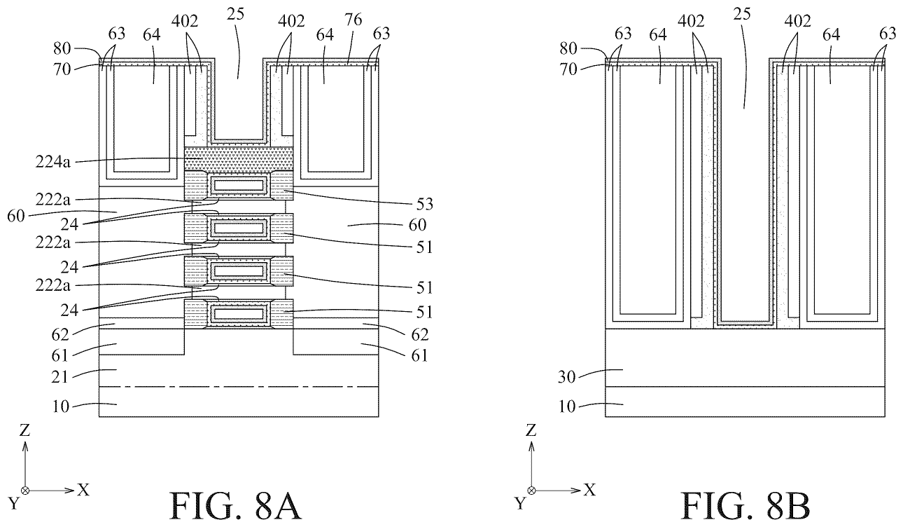

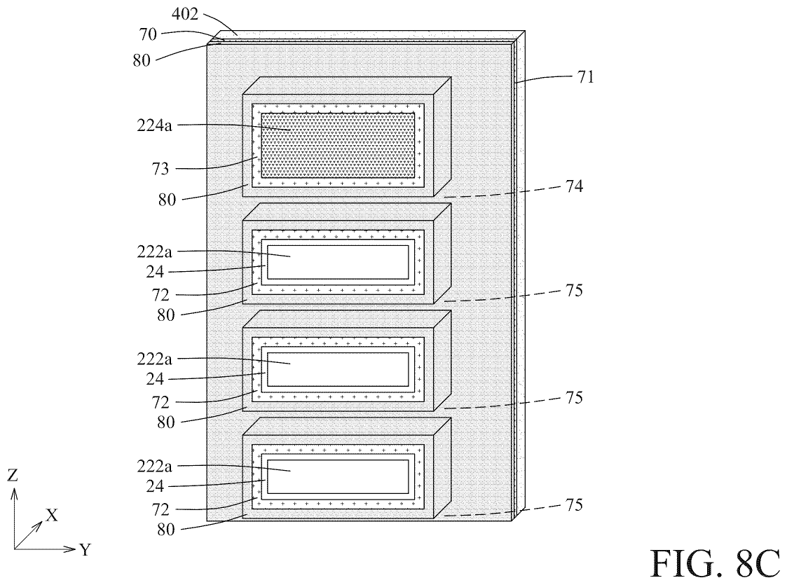

Referring to FIG. 1 and the examples illustrated in FIGS. 8A, 8B and 8C, the method 1 proceeds to step S07, where a cladding layer 80 is formed on the gate dielectric layer 70 (i.e., the regions 71, 72, 73, 74, 75, 76 shown in FIGS. 7A, 7B and 7C). FIGS. 8A, 8B and 8C are views respectively similar to those of FIGS. 7A, 7B and 7C, but illustrating the structure after step S07.

In some embodiments, the cladding layer 80 is made of a material that is different from the dielectric material of the gate dielectric layer 70, so that the cladding layer 80 is able to be selectively removed while the gate dielectric layer 70 is substantially intact due to different etching selectivity ratios. In some embodiments, the cladding layer 80 may be made of silicon oxide, silicon nitride, silicon carbide, silicon oxycarbide, silicon oxynitirde, silicon carbon nitride, silicon oxycarbon nitride, metal oxide (such as aluminum oxide, titanium oxide, etc.), metal nitride (such as aluminum nitride, titanium nitride, etc.), metal oxynitride (such as aluminum oxynitride, etc.), other suitable materials, or combinations thereof. In some embodiments, a film density of the cladding layer 80 is less than a film density of the gate dielectric layer 70. In some embodiments, the film density of the cladding layer 80 may range from about 2 g/cm³ to about 10 g/cm³. In some embodiments, the cladding layer 80 has a thickness ranging from about 1 nm to about 10 nm. In some embodiments, the cladding layer 80 may be formed by CVD, ALD, PVD, or other suitable deposition techniques. The film density and the thickness of the cladding layer 80 are correlated to the degree of modification of the gate dielectric layer 70 in the next step (i.e., in step S08), and the details thereof will be described hereafter.

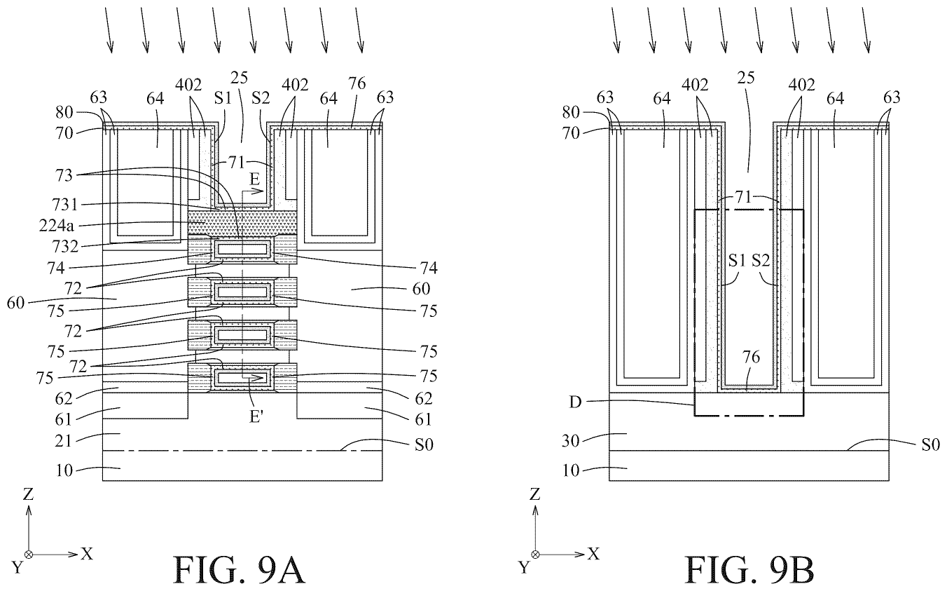

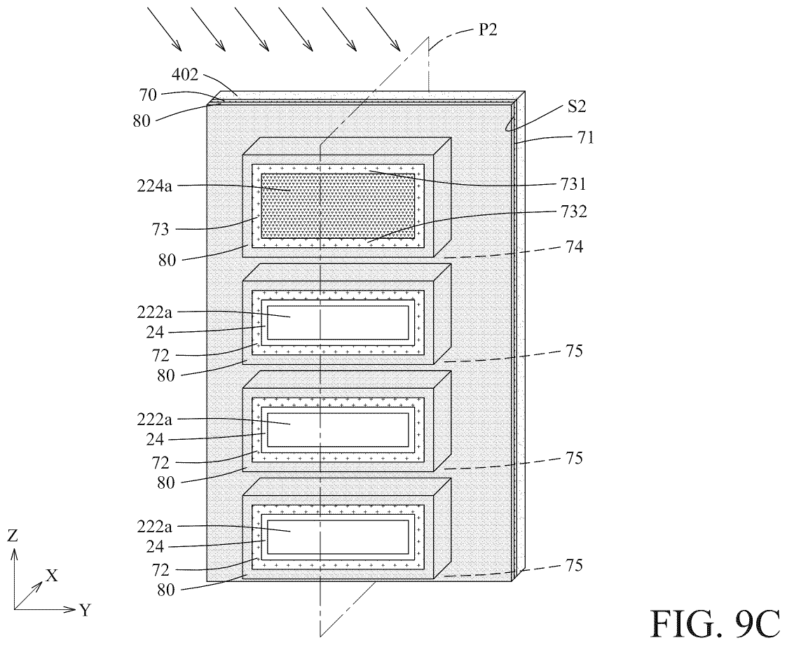

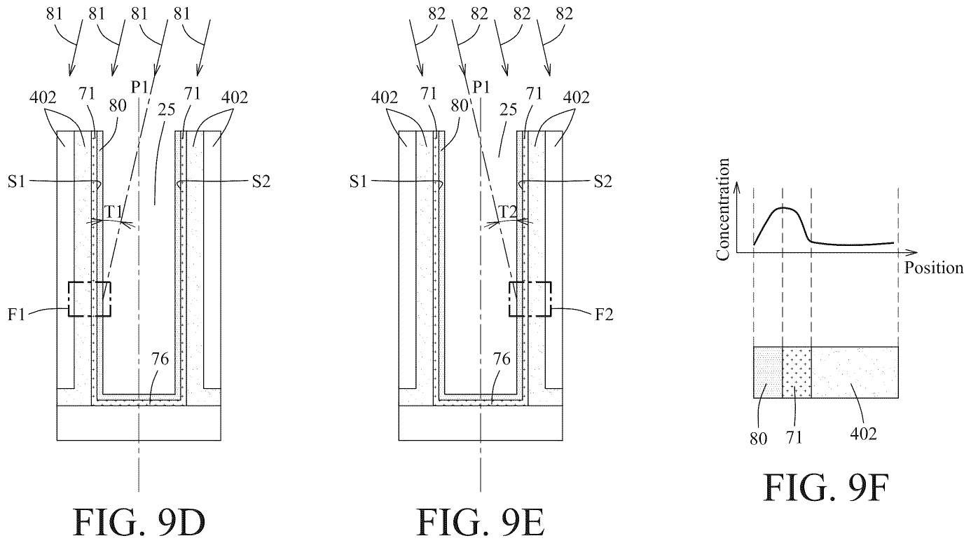

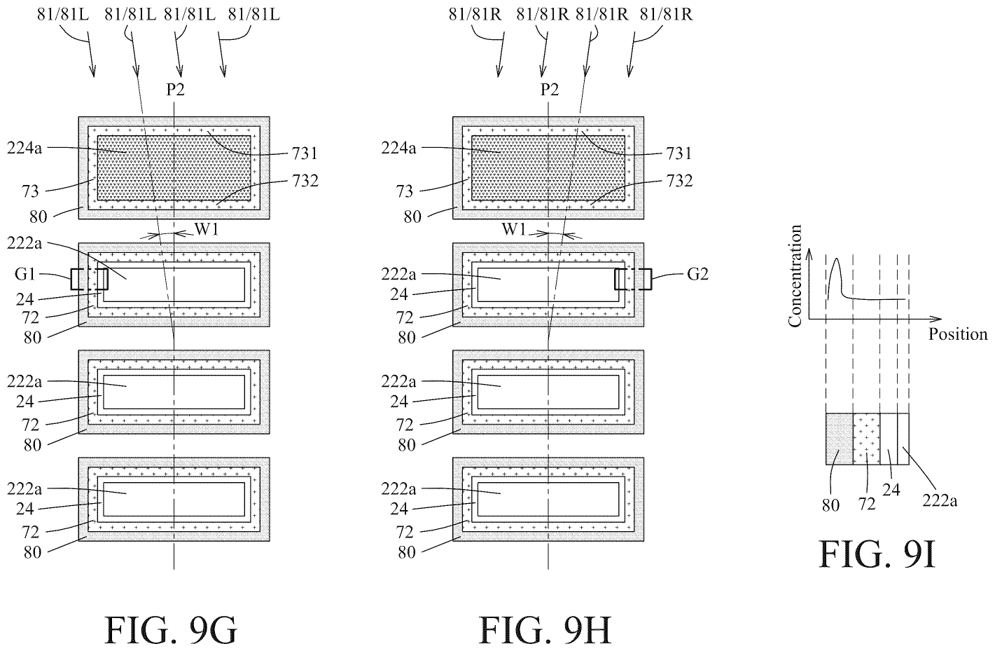

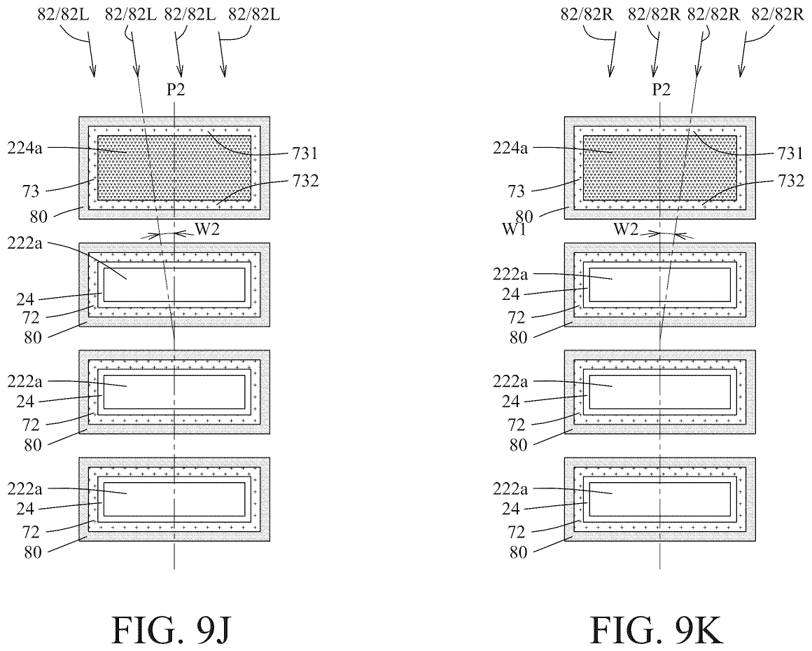

Referring to FIG. 1 and the examples illustrated in FIGS. 9A, 9B and 9C, the method 1 proceeds to step S08, where an implantation process is performed to introduce ions into the gate dielectric layer 70 through the cladding layer 80, so as to permit the gate dielectric layer 70 to be partially modified by the ions. FIGS. 9A, 9B and 9C are views respectively similar to those of FIGS. 8A, 8B and 8C, but illustrating the structure after step S08.

In some embodiments, the ions include an inert element (such as Ar, Kr, Xe, or other suitable inert elements), nitrogen, group IV elements (such as Ge, or other suitable group IV elements), oxygen, a halogen-containing element (such as F, BF₂, or other suitable halogen-containing elements), or combinations thereof.

During the implantation process, since the ions are applied in a predetermined direction, the ions pass through the cladding layer 80 into the regions 71, 73, 76 of the gate dielectric layer 70, while the regions 72, 74, 75 are shielded from the ions by the shielding film 224a, such that a concentration of the ions in each of the regions 71, 73, 76 is greater than a concentration of the ions in each of the regions 72, 74, 75.

As shown in FIGS. 9A and 9C, the third region 73 of the gate dielectric layer 70 has an upper zone 731 and a lower zone 732 which are respectively disposed above and beneath the shielding film 224a. During the implantation process, the ions are introduced into the upper zone 731, while the lower zone 732 is shielded from the ions by the shielding film 224a. Hence, a concentration of the ions in the upper zone 731 is greater than a concentration of the ions in the lower zone 732.

As shown in FIGS. 9A and 9B, the gate dielectric layer 70 has a first dielectric surface S1 and a second dielectric surface S2 which are respectively positioned on the two first regions 71. The first dielectric surface S1 and the second dielectric surface S2 confront each other, and are parallel to each other. Each of the dielectric surfaces S1, S2 extends upwardly in a normal direction that is normal to a top surface S0 of the substrate 10. In some embodiments, the normal direction is parallel to the Z direction.

FIGS. 9D and 9E respectively are enlarged fragmentary views of area D of FIG. 9B in accordance with some embodiments, and respectively illustrate two sub-steps of the implantation process. FIG. 9F is a graph illustrating the variation of a concentration of the ions in area F1 of FIG. 9D (or area F2 in FIG. 9E) in accordance with some embodiments. The result shown in FIG. 9F is obtained after the implantation process.

In some embodiments, the implantation process includes directionally introducing the ions toward the first dielectric surface S1 along first implantation lines 81 (i.e., the first sub-step, see FIG. 9D), and directionally introducing the ions toward the second dielectric surface S2 along second implantation lines 82 (i.e., the second sub-step, see FIG. 9E). The first sub-step may be performed before or after the second sub-step. Each of the first implantation lines 81 forms a first tilt angle T1 relative to the first dielectric surface S1, and each of the second implantation lines 82 forms a second tilt angle T2 relative to the second dielectric surface S2. The first implantation lines 81 are respectively oriented counter to the second implantation lines 82 with respect to a first imaginary plane P1 which is equidistant from the first dielectric surface S1 and the second dielectric surface S2. In some embodiments, the first tilt angle T1 is equal to the second tilt angle T2.

Each of the tilt angles T1, T2 is adjusted based on an aspect ratio of the cavity 25, so as to permit the first regions 71 of the gate dielectric layer 70 to be entirely modified by the ions. In some embodiments, when the aspect ratio of the cavity 25 is relatively high, each of the tilt angles T1, T2 may be relatively small, for example, may range from about 0.1 degree to about 10 degrees. In some other embodiments, when the aspect ratio of the cavity 25 is relatively low, each of the tilt angles T1, T2 may be relatively large, for example, may range from about 10 degrees to about 40 degrees. Referring to FIG. 9F, after the implantation process, each of the concentration of the ions in the cladding layer 80 and the concentration of the ions in the first regions 71 is greater than the concentration of the ions in the gate spacers 402. In other words, the ions are introduced into the first regions 71 of the gate dielectric layer 70.

In some embodiments, each of the first sub-step and the second sub-step includes a first operation and a second operation. FIGS. 9G and 9H respectively are schematic sectional views taken along line E-E′ of FIG. 9A, and respectively illustrate the first and second operations of the first sub-step in accordance with some embodiments. FIGS. 9J and 9K are views respectively similar to FIGS. 9G and 9H, but respectively illustrate the first and second operations of the second sub-step in accordance with some embodiments. FIG. 9I is a graph illustrating the variation of a concentration of the ions in area G1 of FIG. 9G (or in area G2 of FIG. 9H) in accordance with some embodiments. The result shown in FIG. 9I is obtained after the implantation process. It is noted that FIGS. 9G, 9H, 9J and 9K each further illustrates the first or the second implantation lines 81, 82 projected on a Y-Z plane in accordance with some embodiments.

A second imaginary plane P2 is shown in FIG. 9C (see also FIGS. 9G, 9H, 9J, and 9K). The second imaginary plane P2 is normal to each of the first dielectric surface S1 (see FIGS. 9A and 9B), the second dielectric surface S2 and the top surface S0 of the substrate 10 (see FIGS. 9A and 9B).

In some embodiments, as shown in FIGS. 9G and 9H, each of the first implantation lines 81 forms a first twist angle W1 relative to the second imaginary plane P2. In some embodiments, the first implantation lines 81 include first left lines 81L and first right lines 81R, and the first right lines 81R are respectively oriented counter to the first left lines 81L with respect to the second imaginary plane P2. In the first operation of the first sub-step, the ions are directionally introduced toward the first dielectric surface S1 along the first left lines 81L; and in the second operation of the first sub-step, the ions are directionally introduced toward the first dielectric surface S1 along the first right lines 81R. In the first sub-step, the first operation may be performed before or after the second operation.

In some embodiments, as shown in FIGS. 9J and 9K, each of the second implantation lines 82 forms a second twist angle W2 relative to the second imaginary plane P2. The second implantation lines 82 include second left lines 82L and second right lines 82R, and the second right lines 82R are respectively oriented counter to the second left lines 82L with respect to the second imaginary plane P2. In the first operation of the second sub-step, the ions are directionally introduced toward the second dielectric surface S2 along the second left lines 82L; and in the second operation of the second sub-step, the ions are directionally introduced toward the second dielectric surface S2 along the second right lines 82R. In the second sub-step, the first operation may be performed before or after the second operation.

In some embodiments, the first twist angle W1 is equal to the second twist angle W2. In some embodiments, each of the twist angles W1, W2 is zero. In such case, the incident ions can be almost completely blocked by the shielding film 224a and the third region 73 of the gate dielectric layer 70, and thus the ions are less likely to be introduced into the second regions 72 of the gate dielectric layer 70.

In some other embodiments, each of the twist angles W1, W2 may be greater than zero. In certain embodiments, each of the twist angles W1, W2 may be greater than zero and less than about 45 degrees. In certain embodiments, each of the twist angles W1, W2 may slightly greater than zero, for example, ranging from about 5 degrees to about 8 degrees. In such case, each of the tilt angles T1, T2 may be adjusted within a wider range of value, or may be adjusted to a larger value, in comparison to the tilt angles T1, T2 in the case that each of the twist angles W1, W 2 is zero. Furthermore, backscattering of the ions occurring on the dielectric surfaces S1, S2 may be reduced when each of the tilt angles T1, T2 is relatively large, thereby increasing the efficiency of introduction of the ions into the first regions 71. Thus, an implantation energy used in the implantation process may be relatively low, and a dopant concentration of the ions may be also relatively less. Therefore, as shown in FIG. 9I, after the implantation process, the concentration of the ions in the cladding layer 80 is greater than the concentration of the ions in the second regions 72. In addition, the ions are less likely to be detected in the second regions 72 and the channel films 222a.

In some embodiments, the implantation energy may range from about 0.5 keV to about 20 keV. In some embodiments, the dopant concentration may range from about 1E14 ions/cm² to about 1E16 ions/cm². In some embodiments, the implantation process may be performed at a temperature ranging from about −100° C. to about 500° C. The process parameters (e.g., implantation energy, dopant concentration, temperature, etc.) of the implantation process may be adjusted according to practical applications.

It is noted that when the film density of the cladding layer 80 is substantially equal to or greater than the film density of the gate dielectric layer 70 (e.g., greater than about 10 g/cm³), an undesirable degree of backscattering may occur on a surface of the cladding layer 80 during the implantation process. In other words, the majority of the ions will be backscattered on the surface of the cladding layer 80 without entering the first regions 71 of the gate dielectric layer 70. On the contrary, when the film density of the cladding layer 80 is too low (e.g., less than about 2 g/cm³), the cladding layer 80 may not be sufficiently dense to block the incident ions or backscattered ions from entering the second regions 72 of the gate dielectric layer 70. When the cladding layer 80 is too thick (e.g., greater than about 10 nm), the concentration of the ions in the first regions 71 of the gate dielectric layer 70 (i.e., the degree of modification) may be insufficient. On the contrary, when the cladding layer 80 is too thin (e.g., less than about 1 nm), the cladding layer 80 may not be sufficiently thick to block the incident ions or backscattered ions from entering the second regions 72 of the gate dielectric layer 70.

After the implantation process, the gate dielectric layer 70 includes an ion-modified portion and a non-modified portion which are classified according to the degree of modification by the ions. A concentration of the ions in the ion-modified portion is greater than a concentration of the ions in the non-modified portion. The ion-modified portion includes the regions 71, 76 and the upper zone 731 of the third region 73, and the non-modified portion includes the regions 72, 74, 75, and the lower zone 732 of the third region 73.

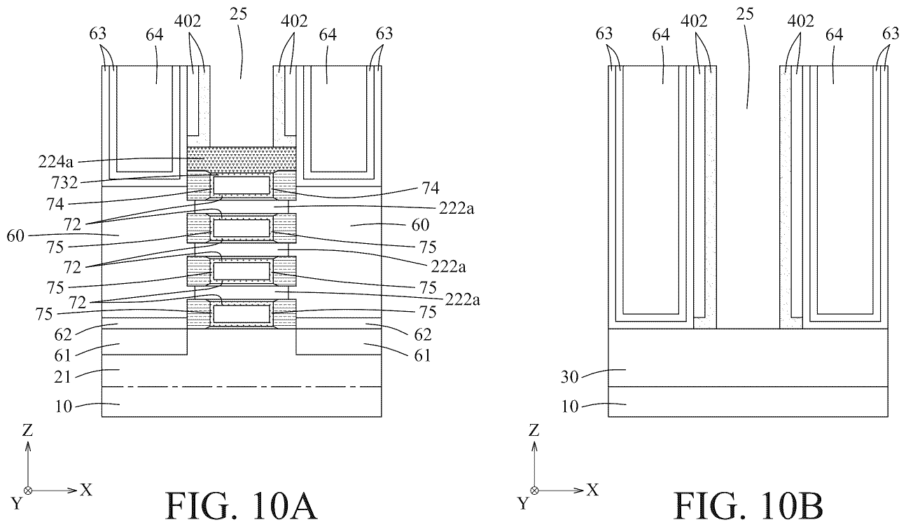

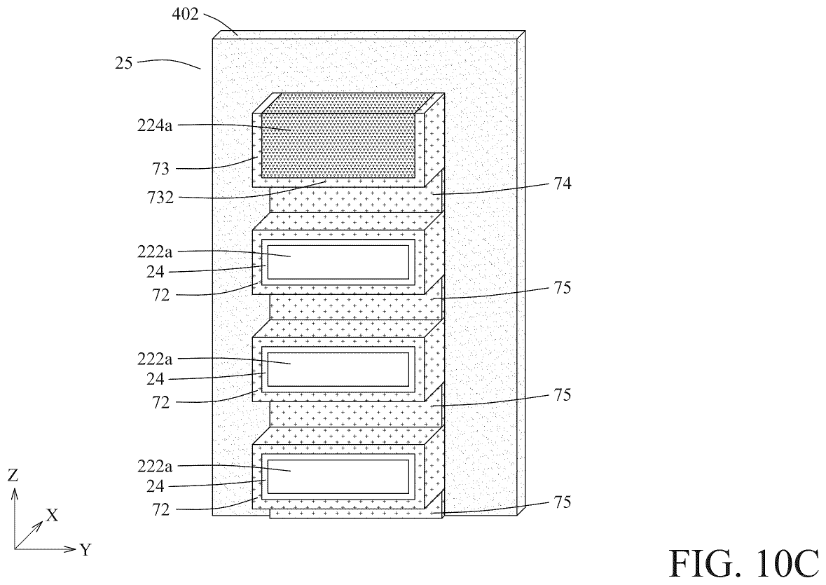

Referring to FIG. 1 and the examples illustrated in FIGS. 10A, 10B and 10C, the method 1 proceeds to step S09, where a first etching process is performed to remove the cladding layer 80 (FIGS. 9A, 9B and 9C) so as to expose the gate dielectric layer 70. Subsequently, a second etching process is performed to remove the ion-modified portion of the gate dielectric layers 70, while leaving the non-modified portion of the gate dielectric layer 70 on the patterned structure 3 (see FIG. 6A). FIGS. 10A, 10B and 10C are views respectively similar to those of FIGS. 9A, 9B and 9C, but illustrating the structure after step S09.

After the second etching process, the gate spacers 402, the shielding film 224a, and the trench isolations 30 are exposed to the cavity 25. The second regions 72 of the gate dielectric layer 70 remain around the channel films 222a. The fifth regions 75 of the gate dielectric layer 70 respectively remain on the lower inner spacers 51. The fourth regions 74 of the gate dielectric layer 70 respectively remain on the upper inner spacers 53. The lower zone 732 of the third region 73 of the gate dielectric layer 70 remain beneath the shielding film 224a.

First etchant(s) used in the first etching process have an etching rate to the cladding layer 80 that is greater than an etching rate to the gate dielectric layer 70, and thus the gate dielectric layer 70 (including the regions 71, 72, 73, 74, 75, 76) is substantially intact during the first etching process. In some embodiments, a ratio of the etching rate to the cladding layer 80 to the etching rate to the gate dielectric layer 70 is greater than about 100:1.

Second etchant(s) used in the second etching process have an etching rate to the ion-modified portion of the gate dielectric layers 70 (e.g., the regions 71, 76 and the upper zone 731 of the third region 73) that is greater than an etching rate to the non-modified portion of the gate dielectric layer 70 (e.g., the regions 72, 74, 75, and the lower zone 732 of the third region 73), and thus the non-modified portion of the gate dielectric layer 70 are substantially intact during the first etching process.

In some embodiments, each of the first and second etching processes may include dry etching, wet etching, other suitable etching techniques, or combinations thereof. In some embodiments, each of the first and second etchant(s) may be gas-phase, liquid-phase, or other suitable states. In certain embodiments, each of the first and second etching processes may be a wet etching process, and may be performed at a temperature ranging from about 10° C. to about 80° C. In some embodiments, the wet etching process may be performed for a time period ranging from about 10 seconds to about 1000 seconds. In some embodiments, each of the first and second etchants used in the wet etching process may include NH₄OH, H₂SO₄, H₂O₂, HCl, H₂O, HF, HNO₃, diluted HF, O₃, H₃PO₄, other suitable etchants, or combinations thereof, but is not limited thereto. In some embodiments, each of the first and second etchants used in the wet etching process may have a pH value ranging from about 0 to about 14.

Referring to FIG. 1 and the examples illustrated in FIGS. 11A, 11B and 11C, the method 1 proceeds to step S10, where a gate electrode 90 is formed to fill the cavity 25 (see FIGS. 10A, 10B and 10C), thereby obtaining the semiconductor structure 2 including a semiconductor device 4. FIGS. 11A, 11B and 11C are views respectively similar to those of FIGS. 10A, 10B and 10C, but illustrating the structure after step S10.

The semiconductor device 4 includes the two source/drain features 60, the channel films 222a and the gate electrode 90. As shown in FIG. 11C, the gate electrode 90 is formed around the channel films 222a and the shielding film 224a. The gate electrode 90 is separated from the channel films 222a respectively by the second regions 72 of the gate dielectric layer 70. As shown in FIGS. 11A and 11B, the gate electrode 90 is in contact with the two gate spacers 402, the lower zone 732, and the regions 72, 74, 75 of the gate dielectric layer 70. The semiconductor device 4 may be referred to as a gate-all-around field-effect transistor (GAAFET).

In some embodiments, the gate electrode 90 may include a work-function material which is provided for adjusting threshold voltage of an n-FET or a p-FET, and an electrically conductive material which has a low resistance and which is provided for reducing overall electrical resistance of the gate electrode 90. In some embodiments, the work-function material may include, for example, but not limited to, titanium, aluminum, tantalum carbide, tantalum carbide nitride, tantalum silicon nitride, or combinations thereof. In some embodiments, the electrically conductive material may include, for example, but not limited to, tungsten, cobalt, ruthenium, iridium, alloy thereof, or combinations thereof. Other materials suitable for the gate electrode 90 are within the contemplated scope of the present disclosure.

In some embodiments, the semiconductor structure 2 may further include additional features, and/or some features present in the semiconductor structure 2 may be modified, replaced, or eliminated without departure from the spirit and scope of the present disclosure. In some embodiments, some steps in the method 1 may be modified, replaced, or eliminated without departure from the spirit and scope of the present disclosure.

For example, in some embodiments, the semiconductor structure 2 may be further formed with two source/drain contacts 91 and a gate contact 92 so as to permit each of the source/drain features 60 and the gate electrode 90 to be controlled by an external power source. The source/drain contacts 91 are respectively formed in the ILD layers 64, and respectively penetrate the CESLs 63 to be respectively connected to the source/drain features 60. The gate contact 92 is electrically connected to the gate electrode 90. In some embodiments, the gate contact 92 extends in the gate electrode 90 and terminates at the shielding feature 224a. In some embodiments, the gate contact 92 extends in the gate electrode 90 and penetrates the shielding feature 224a. In some embodiments, each of the source/drain contacts 91 and the gate contact 92 may include, for example, but not limited to, cobalt, ruthenium, tungsten, molybdenum, alloys thereof, or combinations thereof. Other materials suitable for the source/drain contacts 91 and the gate contact 92 are within the contemplated scope of the present disclosure. Since a high-k dielectric layer (i.e., the first regions 71 of the gate dielectric layer 70 as shown in FIGS. 9A and 9B) is absent between the gate electrode 90 and each of the two source/drain contacts 91, a parasitic capacitance between the gate electrode 90 and each of the two source/drain contacts 91 may be effectively reduced, thereby improving the device performance of the semiconductor structure 2 due to a reduced resistance-capacitance delay (RC delay).

In some other embodiments not shown herein, the semiconductor device 4 may be configured as a planar field-effect transistor (FET), a fin-type field-effect transistor (FinFET), a complementary field-effect transistor (CFET) structure which includes two GAAFETs stacked on one another in the Z direction, or a fork-sheet structure which includes two GAAFETs spaced part from each other in the Y direction through a wall portion which is disposed on one of the trench isolations 30.

In the case that the semiconductor device 4 is configured as a FinFET, the channel films 222a are in contact with each other to form a single channel fin, and the lower inner spacers 51 are absent accordingly. A method for manufacturing the semiconductor structure including the FinFET is similar to the method 1 as described above, except that in step S01, the first sacrificial layers 221 are absent such that the channel layers 222 are in contact with each other to form a single channel layer. The second sacrificial layer 223 and the shielding layer 224 are sequentially formed on the single channel layer opposite to the substrate 10.

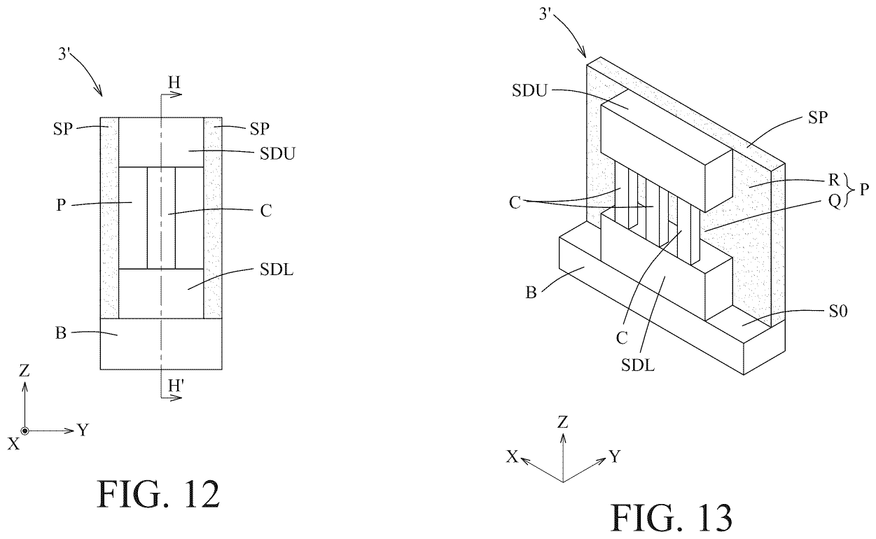

In the exemplary embodiment shown in FIG. 11A, the semiconductor device 4 may be also referred to as a lateral field-effect transistor (LFET), in which the direction of a current flow from a source to a drain is horizontal (e.g., in the X direction). In some other embodiments shown in FIG. 16, the semiconductor device may be configured as a vertical field-effect transistor (VFET, denoted by 4v), in which the direction of a current flow from a source to a drain is vertical (e.g., in the Z direction). FIGS. 12 to 16 are schematic views illustrating formation of the semiconductor structure 2′ (which includes the VFET 4v) at different intermediate stages of the method 1 after appropriate modifications.

FIG. 12 is a cross-sectional view of a patterned structure 3′ for forming the VFET 4v shown in FIG. 16 in accordance with some embodiments. FIG. 13 is a schematic perspective view of the patterned structure 3′, as viewed from a sectional plane illustrated by line H-H′ of FIG. 12 in accordance with some embodiments. The patterned structure 3′ is formed on a base structure (B), and includes channel features (C), an upper source/drain feature (SDU), a lower source/drain feature (SDL), and two dielectric spacers (SP). The base structure (B) may be any suitable structures for forming the VFET 4v thereon, such as a semiconductor substrate similar to the substrate 10. The source/drain features (SDU, SDL) are respectively disposed at two opposite sides of each of the channel features (C) in the Z direction. The two dielectric spacers (SP) are spaced apart from each other in the Y direction. The channel features (C), the upper source/drain feature (SDU) and the lower source/drain feature (SDL) are disposed in a space (P) between the two dielectric spacers (SP). The space (P) has a first space region (Q) located between the upper and lower source/drain features (SDU, SDL), and a second space region (R) is located outside of the upper and lower source/drain features (SDU, SDL).

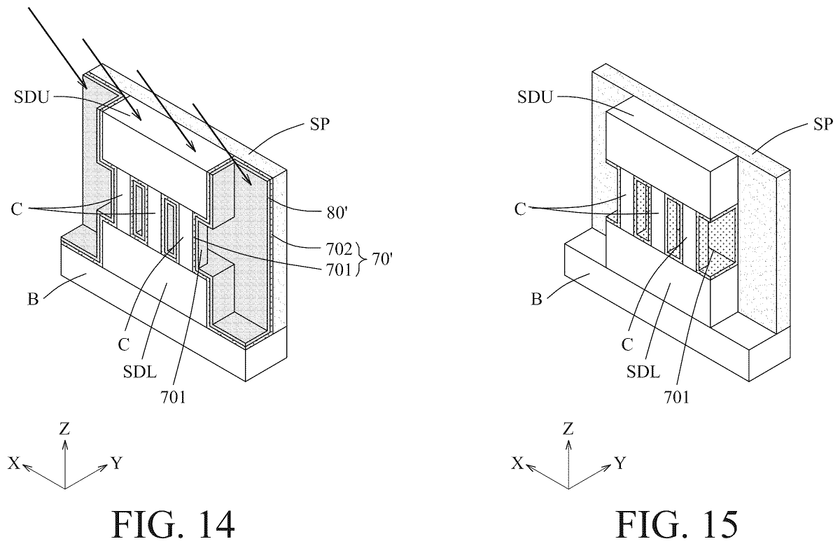

Referring to FIG. 14, a gate dielectric layer 70′ and a cladding layer 80′ are sequentially formed on the patterned structure 3′ (see FIG. 13). Possible materials suitable for the gate dielectric layer 70′ and the cladding layer 80′ are respectively similar to those for the gate dielectric layer 70 and the cladding layer 80 as described above in steps S06 and S07, and thus the details thereof are omitted for the sake of brevity. The gate dielectric layer 70′ has a shielded dielectric part 701 formed along an inner surface of the first space region (Q, see FIG. 13) and an exposed dielectric part 702 formed along an inner surface of the second space region (R, see FIG. 13). After formation of the cladding layer 80′, an implantation process, which is similar to the implantation process as described above in step S08, is performed to introduce ions into the exposed dielectric part 702 through the cladding layer 80, while the shielded dielectric part 701 is shielded from the ions by the upper source/drain feature (SDU). As such a concentration of the ions in the exposed dielectric part 702 is greater than a concentration of the ions in the shielded dielectric part 701. During the implantation process, the upper source/drain feature (SDU) may be protected by a hard mask (not shown) or any suitable features.

Referring to FIG. 15, after the implantation process, the cladding layer 80′ is removed to expose the shielded dielectric part 701 and the exposed dielectric part 702 (see FIG. 14), and then the exposed dielectric part 702 is removed while leaving the shielded dielectric part 701 remaining on the channel features (C).

Referring to FIG. 16, a gate electrode 90′ is formed on the shielded dielectric part 701, thereby obtaining the VFET 4v. The VFET 4v includes the channel features (C), the source/drain features (SDU, SDL), and the gate electrode 90'. The shielded dielectric part 701 is disposed to separate the gate electrode 90′ from the channel features (C) and the source/drain features (SDU, SDL). Possible materials suitable for the gate electrode 90′ are similar to those for the gate electrode 90 as described above in step S10, and thus the details thereof are omitted for the sake of brevity.

In summary, in order to selectively remove a sidewall region (e.g., the first regions 71) of the gate dielectric layer 70 by an etching process while leaving an active region (e.g., the second regions 72) of the gate dielectric layer 70 on the channel films 222a (i.e., the active region is not affected by the etching process), the sidewall region of the gate dielectric layer 70 can be modified by an ion implantation process conducted before the etching process so as to permit the sidewall region of the gate dielectric layer 70 to have an etching rate that is higher than an etching rate of the active region of the gate dielectric layer 70. The shielding film 224a and the cladding layer 80 are provided to protect the active region of the gate dielectric layer 70 from being modified by incident ions or backscattered ions. In addition, by adjusting process parameters (e.g., implantation energy, dopant concentration, the tilt angles T1, T2, the twist angles W1, W2, etc.) of the implantation process, the efficiency of introduction of the ions into the sidewall region of the gate dielectric layer 70 may be increased, and backscattering occurring during the implantation process may be reduced. As such, an etching rate difference between the sidewall region and the active region of the gate dielectric layer 70 can be enlarged. After selectively removing the sidewall region of the gate dielectric layer 70, a parasitic capacitance formed between the gate electrode 90 and one of the source/drain contacts 91 may be significantly reduced. In addition, the selective removal of the gate dielectric layer may also be applied in the formation of VFET 4v.

In accordance with some embodiments of the present disclosure, a method for manufacturing a semiconductor structure includes: forming a gate dielectric layer on a patterned structure, the gate dielectric layer having a first dielectric region and a second dielectric region displaced from each other; forming a cladding layer on the gate dielectric layer, a material of the cladding layer being different from a material of the gate dielectric layer; introducing ions into the first dielectric region through the cladding layer while the second dielectric region is shielded from the ions, such that a concentration of the ions in the first dielectric region is greater than a concentration of the ions in the second dielectric region; and removing the cladding layer to expose the gate dielectric layer; and after removing the cladding layer, removing the first dielectric region to expose a first surface of the patterned structure while the second dielectric region remains on a second surface of the patterned structure.

In accordance with some embodiments of the present disclosure, the method further includes: forming a gate electrode which is in contact with the second dielectric region and the first surface of the patterned structure.

In accordance with some embodiments of the present disclosure, a method for manufacturing a semiconductor structure includes: forming a patterned structure which includes a base structure having a top surface, a channel feature disposed on the top surface of the base structure, and two gate spacers disposed on the top surface of the base structure and respectively disposed at two opposite sides of the channel feature; forming a gate dielectric layer on the patterned structure, the gate dielectric layer having two first dielectric regions respectively formed on the two gate spacers and a second dielectric region formed on the channel feature; forming a cladding layer on the gate dielectric layer, a material of the cladding layer being different from a material of the gate dielectric layer; performing an implantation process such that ions are introduced into the two first dielectric regions through the cladding layer while the second dielectric region is shielded from the ions, such that a concentration of the ions in the second dielectric region is less than a concentration of the ions in each of the two first dielectric regions; removing the cladding layer to expose the gate dielectric layer; and after removing the cladding layer, performing an etching process to remove the two first dielectric regions so as to expose the two gate spacers while the second dielectric region remains on the channel feature.

In accordance with some embodiments of the present disclosure, the patterned structure further includes a shielding feature disposed above and spaced apart from the channel feature. The shielding feature includes a dielectric material. The two gate spacers respectively extend across over two end regions of the shielding feature. The gate dielectric layer further has a third dielectric region which is formed on the shielding feature. During the implantation process, the ions are introduced into the two first dielectric regions and the third dielectric region while the second dielectric region is shielded by the third dielectric region so that the ions are prevented from being introduced into the second dielectric region.

In accordance with some embodiments of the present disclosure, the third dielectric region has an upper zone and a lower zone which are respectively disposed above and beneath the shielding feature. During the implantation process, the ions are introduced into the upper zone while the lower zone is shielded by the shielding feature, so that during the etching process, the upper zone is removed to expose the shielding feature while the lower zone remains beneath the shielding feature.

In accordance with some embodiments of the present disclosure, the two gate spacers are spaced apart from each other in a first direction. The two end regions of the shielding feature are opposite to each other in the first direction. The patterned structure further includes two source/drain features which are disposed on the top surface of the base structure and which are respectively disposed at two opposite sides of the channel feature in the first direction. The two source/drain features are respectively connected to two end regions of the channel feature and respectively spaced apart from the two end regions of the shielding feature.

In accordance with some embodiments of the present disclosure, the patterned structure further includes two upper inner spacers which are spaced apart from each other in the first direction and which are respectively located beneath the two end regions of the shielding feature. Each of the two upper inner spacers is connected to a respective one of the two gate spacers.

In accordance with some embodiments of the present disclosure, the gate dielectric layer further has two fourth dielectric regions which are respectively formed on the two upper inner spacers. During the implantation process, the two fourth dielectric regions are shielded by the shielding feature, such that a concentration of the ions in each of the two fourth dielectric regions is less than a concentration of the ions in each of the two first dielectric regions. During the etching process, the two fourth dielectric regions respectively remain on the two upper inner spacers.

In accordance with some embodiments of the present disclosure, the channel feature is spaced apart from the base structure in a second direction transverse to the first direction. The patterned structure further includes two lower inner spacers which are spaced apart from each other in the first direction and which are respectively located beneath the two end regions of the channel feature. Each of the two lower inner spacers is connected to a respective one of the two gate spacers.

In accordance with some embodiments of the present disclosure, the gate dielectric layer further has two fifth dielectric regions which are respectively formed on the two lower inner spacers. During the implantation process, the two fifth dielectric regions are shielded by the shielding feature, such that a concentration of the ions in each of the two fifth dielectric regions is less than a concentration of the ions in each of the two first dielectric regions. During the etching process, the two fifth dielectric regions respectively remain on the two lower inner spacers.

In accordance with some embodiments of the present disclosure, the method further includes: forming a gate electrode on the channel feature and the shielding feature. The gate electrode is separated from the channel feature by the second dielectric region and is in contact with the two gate spacers.

In accordance with some embodiments of the present disclosure, the gate dielectric layer has a first dielectric surface and a second dielectric surface which are respectively positioned on the two first dielectric regions, and which confront and are parallel to each other. Each of the first dielectric surface and the second dielectric surface extends upwardly in a normal direction that is normal to the top surface of the base structure. The implantation process includes: directionally introducing the ions toward the first dielectric surface along first implantation lines, each of which forms a first tilt angle relative to the first dielectric surface; and directionally introducing the ions toward the second dielectric surface along second implantation lines, each of which forms a second tilt angle relative to the second dielectric surface. The first implantation lines are respectively oriented counter to the second implantation lines with respect to a first imaginary plane which is equidistant from the first dielectric surface and the second dielectric surface.

In accordance with some embodiments of the present disclosure, the first tilt angle is equal to the second tilt angle, and each of the first tilt angle and the second tilt angle ranges from about 0.1 degrees to about 40 degrees.

In accordance with some embodiments of the present disclosure, a second imaginary plane is normal to each of the first dielectric surface, the second dielectric surface and the top surface of the base structure. Each of the first implantation lines forms a first twist angle relative to the second imaginary plane, and each of the second implantation lines forms a second twist angle relative to the second imaginary plane. The first twist angle is equal to the second twist angle.

In accordance with some embodiments of the present disclosure, the first implantation lines include first left lines and first right lines. The first right lines are respectively oriented counter to the first left lines with respect to the second imaginary plane. The second implantation lines include second left lines and second right lines. The second right lines are respectively oriented counter to the second left lines with respect to the second imaginary plane.

In accordance with some embodiments of the present disclosure, each of the first twist angle and the second twist angle ranges from 0 degree to 45 degrees.

In accordance with some embodiments of the present disclosure, a film density of the cladding layer is less than a film density of the gate dielectric layer.

In accordance with some embodiments of the present disclosure, the ions include an inert element, nitrogen, germanium, oxygen, a halogen-containing element, or combinations thereof.

In accordance with some embodiments of the present disclosure, a semiconductor structure includes: a base structure having a top surface; a stack which is disposed on the top surface of the base structure and which includes a channel feature including a semiconductor material, and a shielding feature disposed on the channel feature opposite to the base structure and including a dielectric material, the shielding feature being spaced apart from the channel feature; two dielectric spacers disposed on the top surface of the base structure and respectively disposed at two opposite sides of the stack; a gate dielectric layer including a first dielectric region which is disposed on the channel feature and a second dielectric region which is disposed on the shielding feature; and a gate electrode disposed on the first dielectric region and the second dielectric region, the gate electrode being in contact with the two dielectric spacers.

In accordance with some embodiments of the present disclosure, the semiconductor structure further includes: two source/drain features respectively disposed at two opposite sides of the channel feature; and two isolation features respectively disposed on the two source/drain features. The channel feature has two end regions which respectively extend through the dielectric spacers so that the two end regions are respectively connected to the two source/drain features. The shielding feature has two end regions which respectively extend through the dielectric spacers so that the two end regions are respectively connected to the two isolation features.

In accordance with some embodiments of the present disclosure, a method for manufacturing a semiconductor structure includes: forming a patterned structure which includes two dielectric spacers spaced apart from each other, and a channel feature located in a cavity between the two dielectric spacers; forming a gate dielectric layer on the patterned structure, the gate dielectric layer having two first dielectric regions respectively formed on the two dielectric spacers and a second dielectric region formed on the channel feature; forming a cladding layer on the gate dielectric layer, a material of the cladding layer being different from a material of the gate dielectric layer; performing an implantation process to apply ions to the cladding layer under a predetermined implantation direction so as to permit the ions to pass through the cladding layer into the gate dielectric layer, a concentration of the ions in each of the two first dielectric regions being greater than a concentration of the ions in the second dielectric region; removing the cladding layer to expose the gate dielectric layer; and performing an etching process to remove the two first dielectric regions so as to expose the two dielectric spacers while the second dielectric region remains on the channel feature.

In accordance with some embodiments of the present disclosure, the patterned structure further includes a shielding feature disposed above and spaced apart from the channel feature. The gate dielectric layer further has a third dielectric region which is formed on the shielding feature. During the implantation process, the ions are introduced into the two first dielectric regions and the third dielectric region, and the second dielectric region is shielded by the third dielectric region so that the ions are prevented from being introduced into the second dielectric region. During the etching process, at least a portion of the third dielectric region is removed to expose the shielding feature.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor structure, comprising:
forming a gate dielectric layer on a patterned structure, the gate dielectric layer having a first dielectric region and a second dielectric region displaced from each other;
forming a cladding layer on the gate dielectric layer, a material of the cladding layer being different from a material of the gate dielectric layer;
introducing ions into the first dielectric region through the cladding layer while the second dielectric region is shielded from the ions, such that a concentration of the ions in the first dielectric region is greater than a concentration of the ions in the second dielectric region; and
removing the cladding layer to expose the gate dielectric layer; and
after removing the cladding layer, removing the first dielectric region to expose a first surface of the patterned structure while the second dielectric region remains on a second surface of the patterned structure.

2. The method as claimed in claim 1, further comprising:
forming a gate electrode which is in contact with the second dielectric region and the first surface of the patterned structure.

3. A method for manufacturing a semiconductor structure, comprising:
forming a patterned structure which includes
a base structure having a top surface,
a channel feature disposed on the top surface of the base structure, and
two gate spacers disposed on the top surface of the base structure and respectively disposed at two opposite sides of the channel feature;
forming a gate dielectric layer on the patterned structure, the gate dielectric layer having two first dielectric regions respectively formed on the two gate spacers and a second dielectric region formed on the channel feature;
forming a cladding layer on the gate dielectric layer, a material of the cladding layer being different from a material of the gate dielectric layer;
performing an implantation process such that ions are introduced into the two first dielectric regions through the cladding layer while the second dielectric region is shielded from the ions, such that a concentration of the ions in the second dielectric region is less than a concentration of the ions in each of the two first dielectric regions;
removing the cladding layer to expose the gate dielectric layer; and
after removing the cladding layer, performing an etching process to remove the two first dielectric regions so as to expose the two gate spacers while the second dielectric region remains on the channel feature.

4. The method as claimed in claim 3, wherein
the patterned structure further includes a shielding feature disposed above and spaced apart from the channel feature, the shielding feature including a dielectric material,
the two gate spacers respectively extend across over two end regions of the shielding feature,
the gate dielectric layer further has a third dielectric region which is formed on the shielding feature, and
during the implantation process, the ions are introduced into the two first dielectric regions and the third dielectric region while the second dielectric region is shielded by the third dielectric region so that the ions are prevented from being introduced into the second dielectric region.

5. The method as claimed in claim 4, wherein
the third dielectric region has an upper zone and a lower zone which are respectively disposed above and beneath the shielding feature, and
during the implantation process, the ions are introduced into the upper zone while the lower zone is shielded by the shielding feature, so that during the etching process, the upper zone is removed to expose the shielding feature while the lower zone remains beneath the shielding feature.

6. The method as claimed in claim 4, wherein
the two gate spacers are spaced apart from each other in a first direction,
the two end regions of the shielding feature are opposite to each other in the first direction, and
the patterned structure further includes two source/drain features which are disposed on the top surface of the base structure and which are respectively disposed at two opposite sides of the channel feature in the first direction, the two source/drain features being respectively connected to two end regions of the channel feature and respectively spaced apart from the two end regions of the shielding feature.

7. The method as claimed in claim 6, wherein the patterned structure further includes two upper inner spacers which are spaced apart from each other in the first direction and which are respectively located beneath the two end regions of the shielding feature, each of the two upper inner spacers being connected to a respective one of the two gate spacers.

8. The method as claimed in claim 7, wherein
the gate dielectric layer further has two fourth dielectric regions which are respectively formed on the two upper inner spacers,
during the implantation process, the two fourth dielectric regions are shielded by the shielding feature, such that a concentration of the ions in each of the two fourth dielectric regions is less than a concentration of the ions in each of the two first dielectric regions, and
during the etching process, the two fourth dielectric regions respectively remain on the two upper inner spacers.

9. The method as claimed in claim 6, wherein
the channel feature is spaced apart from the base structure in a second direction transverse to the first direction, and
the patterned structure further includes two lower inner spacers which are spaced apart from each other in the first direction and which are respectively located beneath the two end regions of the channel feature, each of the two lower inner spacers being connected to a respective one of the two gate spacers.

10. The method as claimed in claim 9, wherein
the gate dielectric layer further has two fifth dielectric regions which are respectively formed on the two lower inner spacers,
during the implantation process, the two fifth dielectric regions are shielded by the shielding feature, such that a concentration of the ions in each of the two fifth dielectric regions is less than a concentration of the ions in each of the two first dielectric regions, and
during the etching process, the two fifth dielectric regions respectively remain on the two lower inner spacers.

11. The method as claimed in claim 4, after performing the etching process, further comprising:
forming a gate electrode on the channel feature and the shielding feature, the gate electrode being separated from the channel feature by the second dielectric region and being in contact with the two gate spacers.

12. The method as claimed in claim 3, wherein
the gate dielectric layer has a first dielectric surface and a second dielectric surface which are respectively positioned on the two first dielectric regions, and which confront and are parallel to each other, each of the first dielectric surface and the second dielectric surface extending upwardly in a normal direction that is normal to the top surface of the base structure,
the implantation process includes
directionally introducing the ions toward the first dielectric surface along first implantation lines, each of which forms a first tilt angle relative to the first dielectric surface, and
directionally introducing the ions toward the second dielectric surface along second implantation lines, each of which forms a second tilt angle relative to the second dielectric surface, and
the first implantation lines are respectively oriented counter to the second implantation lines with respect to a first imaginary plane which is equidistant from the first dielectric surface and the second dielectric surface.

13. The method as claimed in claim 12, wherein
the first tilt angle is equal to the second tilt angle, and
each of the first tilt angle and the second tilt angle ranges from about 0.1 degrees to about 40 degrees.

14. The method as claimed in claim 12, wherein
a second imaginary plane is normal to each of the first dielectric surface, the second dielectric surface and the top surface of the base structure,
each of the first implantation lines forms a first twist angle relative to the second imaginary plane,
each of the second implantation lines forms a second twist angle relative to the second imaginary plane, and
the first twist angle is equal to the second twist angle.

15. The method as claimed in claim 14, wherein
the first implantation lines include first left lines and first right lines, the first right lines being respectively oriented counter to the first left lines with respect to the second imaginary plane, and
the second implantation lines include second left lines and second right lines, the second right lines being respectively oriented counter to the second left lines with respect to the second imaginary plane.

16. The method as claimed in claim 14, wherein each of the first twist angle and the second twist angle ranges from 0 degree to 45 degrees.

17. The method as claimed in claim 3, wherein a film density of the cladding layer is less than a film density of the gate dielectric layer.

18. The method as claimed in claim 3, wherein the ions include an inert element, nitrogen, germanium, oxygen, a halogen-containing element, or combinations thereof.

19. A semiconductor structure, comprising:
a base structure having a top surface;
a stack disposed on the top surface of the base structure and including
a channel feature including a semiconductor material, and
a shielding feature disposed on the channel feature opposite to the base structure and including a dielectric material, the shielding feature being spaced apart from the channel feature;
two dielectric spacers disposed on the top surface of the base structure and respectively disposed at two opposite sides of the stack;
a gate dielectric layer including a first dielectric region which is disposed on the channel feature and a second dielectric region which is disposed on the shielding feature; and
a gate electrode disposed on the first dielectric region and the second dielectric region, the gate electrode being in contact with the two dielectric spacers.

20. The semiconductor structure as claimed in claim 19, further comprising:
two source/drain features respectively disposed at two opposite sides of the channel feature; and
two isolation features respectively disposed on the two source/drain features,
the channel feature having two end regions which respectively extend through the dielectric spacers so that the two end regions are respectively connected to the two source/drain features,
the shielding feature having two end regions which respectively extend through the dielectric spacers so that the two end regions are respectively connected to the two isolation features.
